(19) United States
(12) Patent Application Publication
(10) Pub. No.: US 2025/0253226 A1
(43) Pub. Date: Aug. 7, 2025

(54) REDISTRIBUTION SUBSTRATE, MANUFACTURING METHOD OF THE SAME, AND A SEMICONDUCTOR PACKAGE INCLUDING THE SAME

(71) Applicant: Samsung Electronics Co., Ltd., Suwon-si (KR)

(72) Inventor: JUNGHOON KANG, Suwon-si (KR)

(21) Appl. No.: 18/919,915

(22) Filed: Oct. 18, 2024

(30) Foreign Application Priority Data
Feb. 7, 2024 (KR) 10-2024-0019140

(51) Int. Cl. H01L 23/498; H01L 21/48; H01L 25/16

(52) U.S. Cl. CPC H01L 23/49838; H01L 21/4857; H01L 23/49822; H01L 25/16

(57) ABSTRACT

A redistribution substrate including an insulating layer, and a first wiring layer and a second wiring layer of which at least a portion is embedded in the insulating layer. The first wiring layer and the second wiring layer have different widths, and the first wiring layer and the second wiring layer have different surface roughness.

### CROSS-REFERENCE TO RELATED APPLICATION

This application claims the benefit of priority under 35 U.S.C. § 119 to Korean Patent Application No. 10-2024-0019140 filed in the Korean Intellectual Property Office on Feb. 7, 2024, the entire content of which is incorporated herein by reference.

### BACKGROUND

### 1. Field

The present disclosure relates to a redistribution substrate, a manufacturing method thereof, and a semiconductor package including the same.

### 2. Description of the Related Art

A semiconductor chip included in a semiconductor package may be electrically connect to an external electronic part or device through a redistribution substrate and a connection portion. As the size of the semiconductor package is reduced, the size of a predetermined wiring layer in the redistribution substrate may also be reduced. When a wiring layer with a small pattern size is formed on the redistribution substrate, the wiring layer with a small pattern size may be lost or a contact characteristic may be lowered by an undercut in a process for removing a seed layer.

### SUMMARY

The present disclosure attempts to provide a redistribution substrate, a manufacturing method thereof, and a semiconductor package including the same for preventing a loss of a fine pattern, an undercut, and deterioration of a contact characteristic.

The object of the present disclosure is not limited to the above-described object, and it may be expanded in various ways in the range of the ideas and the areas of the present disclosure.

An embodiment of the present disclosure provides a redistribution substrate including: an insulating layer, and a first wiring layer and a second wiring layer of which at least a portion is embedded in the insulating layer, wherein the first wiring layer and the second wiring layer have different widths, and the first wiring layer and the second wiring layer have different surface roughness.

Another embodiment of the present disclosure provides a method for manufacturing a redistribution substrate including: forming a seed layer on an insulating layer; forming, within a first region of the insulating layer, a first wiring layer on the seed layer, and forming, within a second region of the insulating layer, a second wiring layer on the seed layer, the second wiring layer having a width that is different from a width of the first wiring layer; removing the seed layer formed on the second region and not overlapping the second wiring layer by a first method; and removing the seed layer formed on the first region and not overlapping the first wiring layer by a second method that is different from the first method.

Another embodiment of the present disclosure provides a semiconductor package including: a first redistribution substrate and a second redistribution substrate; and a semiconductor chip disposed between the first redistribution substrate and the second redistribution substrate, wherein the first redistribution substrate includes an insulating layer, and a first wiring layer and a second wiring layer at least partly embedded in the insulating layer, the first wiring layer and the second wiring layer have different widths, and the first wiring layer and the second wiring layer have different surface roughness.

According to the embodiments, the redistribution substrate the manufacturing method thereof, and the semiconductor package including the same for preventing a loss of a fine pattern, an undercut, and deterioration of a contact characteristic may be provided.

The object of the present disclosure is not limited to the above-described object, and it may be expanded in various ways in the range of the ideas and the areas of the present disclosure.

### BRIEF DESCRIPTION OF THE DRAWINGS

FIG. 1 shows a semiconductor package according to an embodiment.

FIG. 2 shows a cross-sectional view of an enlarged region of FIG. 1.

FIG. 3 to FIG. 12 show cross-sectional views on a method for manufacturing a redistribution substrate according to an embodiment.

FIG. 13 and FIG. 14 show electron microscope photographs on a result of an experimental example.

FIG. 15 shows a cross-sectional view on a semiconductor package according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of this disclosure.

Parts that are irrelevant to the description will be omitted to clearly describe the present disclosure, and the same elements will be designated by the same reference numerals throughout the specification.

The accompanying drawings are provided only in order to allow embodiments disclosed in the present specification to be easily understood and are not to be interpreted as limiting the spirit disclosed in the present specification, and it is to be understood that the present disclosure includes all modifications, equivalents, and substitutions without departing from the scope and spirit of the present disclosure.

The size and thickness of each configuration shown in the drawings are arbitrarily shown for better understanding and ease of description. However, the embodiments are not limited thereto. In the drawings, the thickness of layers, films, panels, regions, etc., are enlarged for clarity. The thicknesses of some layers and areas are exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

Unless explicitly described to the contrary, the word “comprise”, and variations such as “comprises” or “comprising”, will be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

Throughout the specification, when it is described that a part is “connected” to another part, the part may be “directly connected” to the other element, may be “connected” to the other part through a third part, or may be connected to the other part physically or electrically, and they may be referred to by different titles depending on positions or functions, but respective portions that are substantially integrated into one body may be connected to each other. When an element is referred to as being “directly connected” or “directly coupled” to another element, or as “contacting,” “in contact with,” or “contact” another element, there are no intervening elements present at the point of contact.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

Various embodiment and variations will now be described with reference to accompanying drawings.

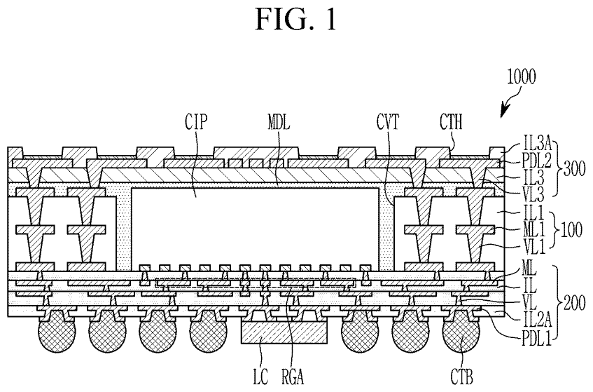

Referring to FIG. 1, a semiconductor package 1000 according to an embodiment may include a connection substrate 100, a first redistribution substrate 200 and a second redistribution substrate 300 disposed below/above the connection substrate 100, and a semiconductor chip CIP installed in the connection substrate 100. The semiconductor package 1000 according to the present embodiment may be a lower package.

The connection substrate 100 may have a through hole CVT penetrating the inside thereof, and the semiconductor chip CIP may be installed in the through hole CVT of the connection substrate 100.

The connection substrate 100 may be disposed on the first redistribution substrate 200, and the second redistribution substrate 300 may be disposed on the connection substrate 100.

The connection substrate 100 may include an insulating layer IL1, connection layers ML1 of which at least a portion is embedded into the insulating layer IL1, and vias VL1 disposed in the insulating layer IL1 and connecting the connection layers ML1. Some of the connection layers ML1 disposed among the connection layers ML1 may be connected to the first redistribution substrate 200, and some of connection layers ML1 disposed among the connection layers ML1 may be connected to the second redistribution substrate 300.

The first redistribution substrate 200 may include insulating layers IL, redistribution layers ML of which at least a portion is embedded in the insulating layers IL, vias VL for connecting the redistribution layers ML, an additional insulating layer IL2A disposed below the insulating layer IL, and connection pads PDL1 connected to the redistribution layers ML through via holes of the additional insulating layer IL2A.

The insulating layers IL may include an organic material such as a photo-imageable dielectric (PID) material. The photosensitive insulating material may, for example, include at least one of a photosensitive polyimide, a polybenzo oxazole, a phenol-based polymer, and a benzocyclobutene-based polymer, to which the embodiment is not limited. The stacking number of the insulating layers IL may vary. For example, the insulating layers IL may include the same material, and an interface between the adjacent insulating layers IL may not be distinguished.

Solder balls CTB may be disposed on a lower surface of the first redistribution substrate 200 and may be connected to the connection pads PDL1. The solder balls CTB may include a solder material. The solder material may include, for example, tin, bismuth, lead, silver, and alloys thereof. However, the embodiments are not limited thereto.

A passive element LC may be connected to some of the connection pads PDL1 of the first redistribution substrate 200.

The type of passive element LC may vary. For example, the passive element LC may be a land side capacitor (LSC), a multilayer ceramic capacitor (MLCC), a low inductance chip capacitor (LICC), an inductor, and an integrated passive device (IPD. However, the embodiments are not limited thereto. Multiple passive elements LC may be arranged, and in this case, they may be the same or may be different from each other.

A molding layer MDL may fill a space between the semiconductor chip CIP and the connection substrate 100, a space between the semiconductor chip CIP and the first redistribution substrate 200, and a space between the connection substrate 100 and the second redistribution substrate 300. The molding layer MDL may include an adhesive insulating film such as an Ajinomoto build up film (ABF) and may include an insulating polymer such as an epoxy-based polymer. However, the embodiments are not limited thereto.

The second redistribution substrate 300 may be disposed on the molding layer MDL and the connection substrate 100.

The second redistribution substrate 300 may include an insulating layer IL3, pads PDL2 disposed on the insulating layer IL3, an additional insulating layer IL3A disposed on the insulating layer IL3 and having contact holes CTH overlapping the pads PDL2, and vias VL3 disposed in the insulating layer IL3 and connecting the pads PDL2 and the connection layers ML1 of the connection substrate 100. Portions of the additional insulating layer IL3A may contact a top surface of the pad PDL2. The pads PDL2 of the second redistribution substrate 300 may be connected to an upper package to be described.

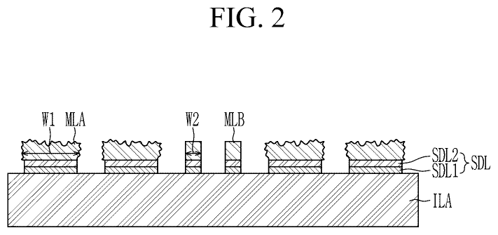

The redistribution substrate according to an embodiment will now be described with reference to FIG. 2 together with FIG. 1. FIG. 2 shows a cross-sectional view of an enlarged region of FIG. 1. FIG. 2 shows a region RGA of FIG. 1.

Referring to FIG. 2, the redistribution substrate may include wiring layers MLA and MLB disposed on the insulating layer ILA. The insulating layer ILA may be a portion of the insulating layer IL of FIG. 1. An additional insulating layer of the insulating layer IL of FIG. 1 may be disposed between the wiring layers MLA and MLB on the insulating layer ILA so that at least portions of the wiring layers MLA and MLB may be embedded in the insulating layer IL of FIG. 1.

The wiring layers MLA and MLB may include first wiring layers MLA and second wiring layers MLB with different widths. A first width W1 of the first wiring layers MLA may be greater than a second width W2 of the second wiring layers MLB. The respective widths of the first wiring layers MLA may be different from each other, and the respective widths of the second wiring layers MLB may be different from each other, and the least width from among the respective widths of the first wiring layers MLA may be greater than the greatest width from among the respective widths of the second wiring layers MLB.

The first wiring layers MLA may be a general circuit pattern, and the second wiring layers MLB may be a fine circuit pattern. For example, the width of the second wiring layers MLB may be equal to or less than about 1 μm to about 3 μm, and more specifically, it may be equal to or less than about 2 μm, and a distance between the adjacent second wiring layers MLB may be equal to or less than about 2 μm to about 4 μm, more specifically, it may be equal to or less than about 3p m. However, the embodiments are not limited thereto.

A seed layer SDL may be disposed below the first wiring layers MLA and the second wiring layers MLB. The seed layer SDL may include the same metal as the first wiring layers MLA and the second wiring layers MLB.

The seed layer SDL may include a first seed layer SDL1 and a second seed layer SDL2 disposed on the first seed layer SDL1, the first seed layer SDL1 may include a metal that has an excellent contact characteristic with the insulating layer ILA, and the second seed layer SDL2 may include the same metal as the first wiring layers MLA and the second wiring layers MLB. For example, the first seed layer SDL1 may include titanium and the second seed layer SDL2 may include copper. However, the embodiments are not limited thereto.

Surface roughness of the first wiring layers MLA may be different from surface roughness of the second wiring layers MLB. More specifically, the surface roughness of the first wiring layers MLA may be greater than the surface roughness of the second wiring layers MLB. For example, surfaces of the first wiring layers MLA may be wet etched, and surfaces of the second wiring layers MLB may not be wet etched.

Although not shown in FIG. 2, referring to FIG. 1, the redistribution substrate may further include an insulating layer IL disposed on the first wiring layers MLA and the second wiring layers MLB, and the first wiring layers MLA and the second wiring layers MLB may be embedded by the insulating layer IL. Vias VL overlapping at least some of the first wiring layers MLA and the second wiring layers MLB may be disposed in the insulating layer IL disposed on the first wiring layers MLA and the second wiring layers MLB.

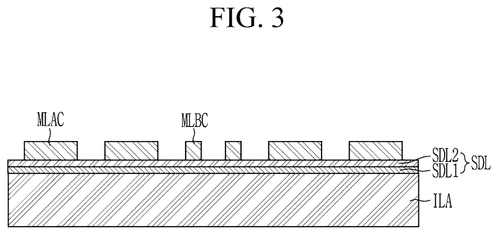

A method for manufacturing a redistribution substrate according to an embodiment will now be described with reference to FIG. 3 to FIG. 12 together with FIG. 1 and FIG. 2. FIG. 3 to FIG. 12 show cross-sectional views on a method for manufacturing a redistribution substrate according to an embodiment.

Referring to FIG. 3, the seed layer SDL may be deposited on the insulating layer ILA, and first preliminary wiring layers MLAC and second preliminary wiring layers MLBC may be formed in a region on the seed layer SDL. For example, a blocking layer may be formed on a portion that is exclusive of a region where the first wiring layers MLA and the second wiring layers MLB will be formed on the seed layer SDL, and a metal may be plated on a portion of the seed layer SDL that is not covered by the blocking layer so that the first preliminary wiring layers MLAC and the second preliminary wiring layers MLBC may be formed. However, the embodiments are not limited thereto, and the first preliminary wiring layers MLAC and the second preliminary wiring layers MLBC may be formed by other methods.

As described above, the seed layer SDL may include a first seed layer SDL1 and a second seed layer SDL2 disposed on the first seed layer SDL1. However, the embodiments are not limited thereto.

The first preliminary wiring layers MLAC may have the first width W1, the second preliminary wiring layers MLBC may have the second width, and the first width W1 may be greater than the second width W2.

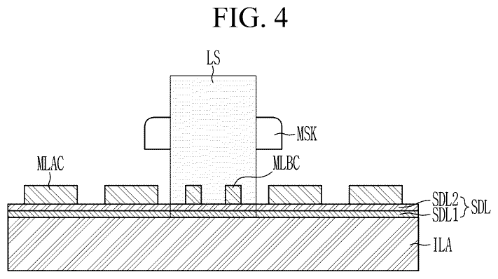

Referring to FIG. 4, laser beams LS may be irradiated to the second preliminary wiring layers MLBC disposed in the region where the second wiring layers MLB will be formed by using a mask MSK.

The laser beams LS may be XeC1 excimer laser beams, they have a wavelength of about 300 nm to about 310 nm, more specifically, the wavelength of about 308 nm may be utilized. However, the embodiments are not limited thereto. The laser beams LS may be KrF excimer laser beams, they have the wavelength of about 241 nm to about 255 nm, more specifically, the wavelength of about 248 nm may be utilized. However, the embodiments are not limited thereto.

The laser beams LS may be ultraviolet laser beams, for example, the laser beams LS may be diode pumping solid state (DPSS) laser beams, and may have the wavelength of about 335 nm to about 350 nm, more specifically, the wavelength of about 343 nm may be utilized. However, the embodiments are not limited thereto.

The laser beams LS may have a linear beam form, a long-axis length of the laser beams LS may be about 1 mm to about 1500 mm, a short-axis length of the laser beams LS may be about 20 μm to about 410 μm. However, the embodiments are not limited thereto.

The laser beams LS may be XeC1 excimer laser beams, the long axis of the laser beams LS in a linear beam form may be about 1 mm to about 1500 mm, the short axis may be about 390 μm to about 410 μm, more specifically, about 400 μm, an area in which linear beams of the laser beams LS are irradiated may be about 0.004 cm2 to about 2.4 cm2, a frequency of the laser beams LS may be about 0.3 kHz to about 0.6 kHz, power of the laser beams LS may be about 300 W, energy of the laser beams LS may be about 1,000 mJ, energy density of the laser beams LS may be about 100 mJ/cm2 to about 250,000 mJ/cm2, more specifically, the energy density of the laser beams LS may be 300 mJ/cm2 to about 625 mJ/cm2. However, the embodiments are not limited thereto.

The laser beams LS may be diode pumping solid state (DPSS) laser beams, the long axis of the laser beams LS in a linear beam form may be about 4 mm to about 1500 mm, the short axis thereof may be about 25 μm to about 35 μm, more specifically, about 30 μm, the area in which the linear beams of the laser beams LS are irradiated may be about 0.0012 cm2 to about 0.18 cm2, the frequency of the laser beams LS may be about 9 kHz to about 11 kHz, more specifically, about 10 kHz, the power of the laser beams LS may be about 400 W to about 800 W, the energy of the laser beams LS may be about 40 mJ to about 80 mJ, the energy density of the laser beams LS may be about 100 mJ/cm2 to about 666,667 mJ/cm2, more specifically, the energy density of the laser beams LS may be 667 mJ/cm2 to about 1,333 mJ/cm2. However, he embodiments are not limited thereto.

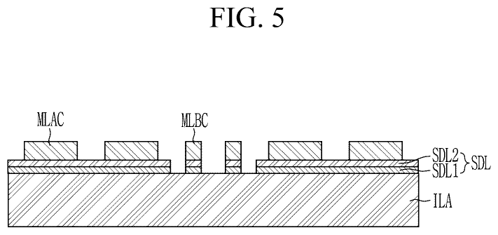

Referring to FIG. 5, the seed layer SDL disposed in the region where the laser beams LS are irradiated and not overlapping the second preliminary wiring layers MLBC may be removed.

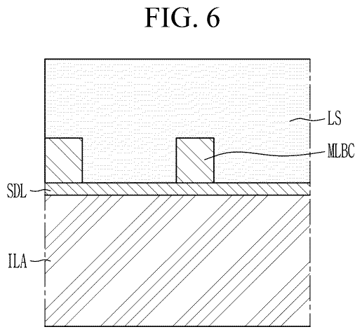

A method for removing the seed layer SDL by using the laser beams LS will now be described in detail with reference to FIG. 6 to FIG. 9.

As shown in FIG. 6, the laser beams LS may be irradiated to the region in which the second preliminary wiring layers MLBC are disposed.

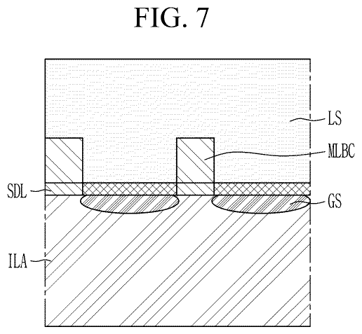

As shown in FIG. 7, a relatively less amount of the laser energy may reach the seed layer SDL disposed below the second preliminary wiring layers MLBC, a relatively greater amount of the laser energy may reach the seed layer SDL disposed between the second preliminary wiring layers MLBC and not covered by the second preliminary wiring layers MLBC, and the laser energy may reach the insulating layer ILA disposed below the seed layer SDL which the relatively greater amount of the laser energy reaches to form an overheated region GS. The laser energy may reach the overheated region GS and gas may be generated.

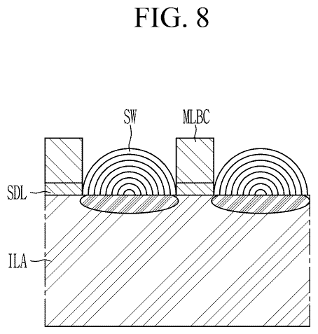

Referring to FIG. 8, a gas layer of the overheated region GS formed in the insulating layer ILA disposed below the seed layer SDL not covered by the second preliminary wiring layers MLBC and which the relatively greater amount of the laser energy reaches may spurt on a surface of the insulating layer ILA, and shock waves SW may be applied to the seed layer SDL not covered by the second preliminary wiring layers MLBC by the spurting gas layer.

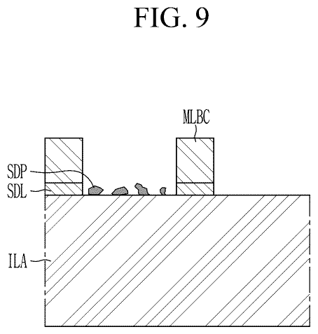

Referring to FIG. 9, as the gas layer heated and generated by the laser energy spurts outside and the shock wave SW is applied to the seed layer SDL, the thin seed layer SDL is destroyed to be seed particles SDP, and the seed particles SDP may be easily removed by a cleaning process.

As described, the second wiring layers MLB may be formed by removing the seed layer SDL not overlapping the second preliminary wiring layers MLBC by using the laser beams LS.

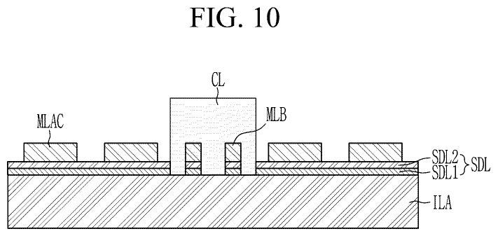

Referring to FIG. 10, a cover layer CL may be formed to cover the second wiring layers MLB and expose the region in which the first wiring layers MLA will be formed.

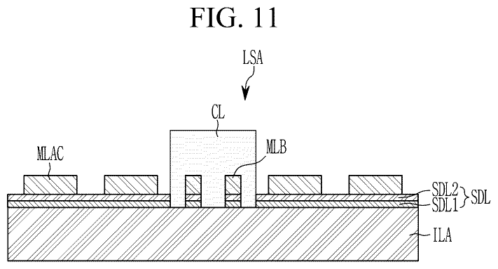

Referring to FIG. 11, the seed layer SDL not covered by the first preliminary wiring layers MLAC may be etched by using the cover layer CL covering the second wiring layers MLB as a mask (LSA). The process for etching the seed layer SDL (LSA) may be a wet etching process.

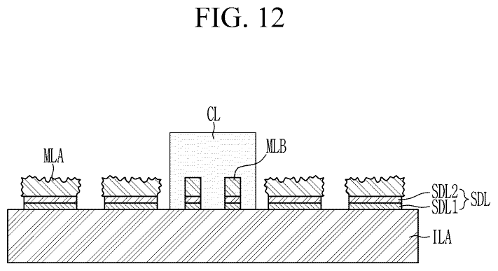

Referring to FIG. 12, first wiring layers MLA may be formed through etching the seed layer SDL (LSA) by using the cover layer CL covering the second wiring layers MLB as a mask. While etching the seed layer SDL, surfaces of the first wiring layers MLA may be partly etched so surface roughness of the first wiring layers MLA may be relatively large. Differing from this, while etching the seed layer SDL, the second wiring layers MLB may be covered and protected by the cover layer CL so they may not be etched.

When the first wiring layers MLA that are general circuit patterns and the second wiring layers MLB that are fine circuit patterns, which may have different widths and gaps, are simultaneously formed, and the etching process is performed to remove the seed layer SDL, the second wiring layers MLB that are fine circuit patterns may be etched to be lost or undercuts may be generated to deteriorate the contact characteristic with other layers.

However, according to the herein described embodiment, when the second wiring layers MLB that are fine circuit patterns are formed, the seed layer SDL may be removed according to the irradiation of laser beams, and the etching process for removing the seed layer SDL around the first wiring layers MLA is performed while the second wiring layers MLB are covered and protected by the cover layer CL so that the second wiring layers MLB that are fine circuit patterns may not be etched during the etching process. Further, the second wiring layers MLB may be covered and protected by the cover layer CL, and then the etching process for removing the seed layer SDL around the first wiring layers MLA may be performed so that the surface of the first wiring layers MLA may be partly etched during the etching process, thereby the surface roughness of the first wiring layers MLA may be relatively large and the surface roughness of the second wiring layers MLB may be relatively small.

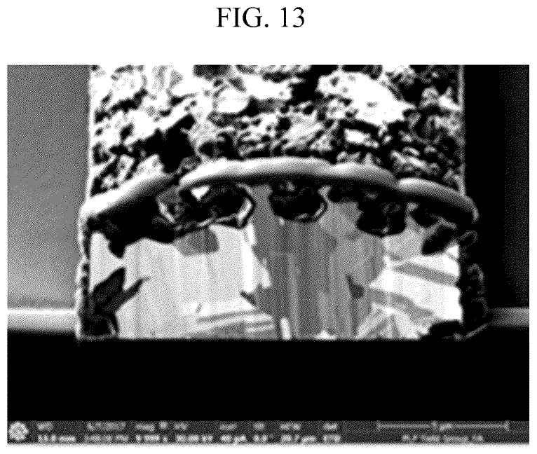

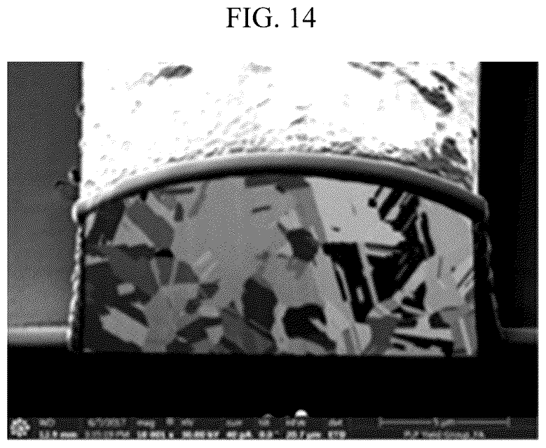

A result of an experimental example will now be described with reference to FIG. 13 and FIG. 14. FIG. 13 and FIG. 14 show electron microscope photographs on a result of an example.

In the present experimental example, as like the method for manufacturing a redistribution substrate according to an embodiment, the seed layer SDL may be removed according to the irradiation of laser beams when the second wiring layers MLB that are fine circuit patterns are formed, and the etching process for removing the seed layer SDL around the first wiring layers MLA may be performed while the second wiring layers MLB may be covered and protected by the cover layer CL. Then, the electron microscope photographs of some of the first wiring layers MLA and the second wiring layers MLB were taken. FIG. 13 shows an electron microscope photograph on one of the first wiring layers MLA. FIG. 14 shows an electron microscope photograph on one of the second wiring layers MLB.

Referring to FIG. 13 and FIG. 14, it may be found that the surface roughness of the first wiring layers MLA is relatively large and the surface roughness of the second wiring layers MLB is relatively small, and the second wiring layers MLB that are fine circuit patterns are well formed so that no undercuts may be generated.

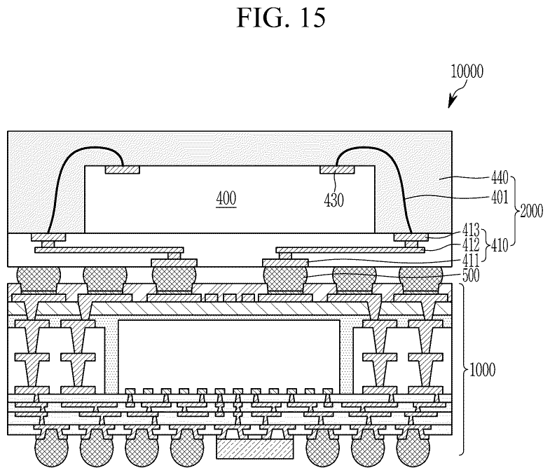

A semiconductor package 10000 according to an embodiment will now be described with reference to FIG. 15. FIG. 15 shows a cross-sectional view on a semiconductor package according to an embodiment.

Referring to FIG. 15, the semiconductor package 10000 may include a lower semiconductor package 1000 and an upper semiconductor package 2000.

The lower semiconductor package 1000 may substantially correspond to the semiconductor package 1000 described with reference to FIG. 1. For example, as detailed in FIG. 1, the lower semiconductor package 1000 may include a connection substrate 100, a first redistribution substrate 200, a second redistribution substrate 300, and a semiconductor chip CIP installed in the connection substrate 100.

As described with reference to FIG. 2, the first redistribution substrate 200 may include wiring layers MLA and MLB, the wiring layers MLA and MLB may include a first wiring layers MLA and a second wiring layers MLB with different widths, and the first width W1 of the first wiring layers MLA may be greater than the second width W2 of the second wiring layers MLB. The first wiring layers MLA of the first redistribution substrate 200 may be general circuit patterns, and the second wiring layers MLB may be fine circuit patterns. The seed layer SDL may be disposed below the first wiring layers MLA and the second wiring layers MLB. The surface roughness of the first wiring layers MLA of the first redistribution substrate 200 may be different from the surface roughness of the second wiring layers MLB. More specifically, the surface roughness of the first wiring layers MLA may be greater than the surface roughness of the second wiring layers MLB. For example, the surfaces of the first wiring layers MLA may be wet etched, and the surfaces of the second wiring layers MLB may not be wet etched.

The upper semiconductor package 2000 may include an upper substrate 410, an upper semiconductor chip 400, and an upper molding layer 440.

The upper substrate 410 may be a printed circuit board (PCB) or a redistribution layer.

The first metal pad 411 and the second metal pad 413 may be disposed on a lower surface and an upper surface of the upper substrate 410.

The metal wire 412 may be disposed in the upper substrate 410, and the metal wire 412 may electrically connect the first metal pad 411 and the second metal pad 413.

The upper semiconductor chip 400 may include a chip pad 430.

The upper semiconductor chip 400 may be of a type different from the type of the semiconductor chip CIP of the lower semiconductor package 1000. For example, the upper semiconductor chip 400 may be a memory chip. However, the embodiments are not limited thereto.

A bonding wire 401 may be disposed on the upper semiconductor chip 400, and the bonding wire 401 may electrically connect the chip pad 430 of the upper semiconductor chip 400 and the second metal pad 413.

Differing from what is shown, the bonding wire 401 may be omitted, and the upper semiconductor chip 400 may be mounted on the upper substrate 410 by a flip chip method. For example, upper bumps (not shown) may be disposed between the upper substrate 410 and the upper semiconductor chip 400, and the upper substrate 410 may be electrically connected to the upper semiconductor chip 400 through the upper bumps. In this case, the chip pad 430 of the upper semiconductor chip 400 may be disposed on a lower surface of the upper semiconductor chip 400.

The upper semiconductor package 2000 may include an upper molding layer 440. The upper molding layer 440 may be disposed on the upper substrate 410 and may cover the upper semiconductor chip 400. The upper molding layer 440 may cover the bonding wire 401. The upper molding layer 440 may include an insulating polymer such as an epoxy-based molding compound. However, the embodiments are not limited thereto. The upper molding layer 440 may be omitted.

Although not shown, the upper semiconductor package 2000 may further include a heat dissipation structure (not shown). The heat dissipation structure may be disposed on the upper surface of the upper semiconductor chip 400 and the upper surface of the upper molding layer 440. The heat dissipation structure may, for example, include a heat sink, a heat slug, and a thermal interface material (TIM) layer, and the heat dissipation structure may include a metal. However, the embodiments are not limited thereto.

The first metal pad 411 of the upper substrate 410 may be connected to the pads PDL2 of the lower semiconductor package 1000 through the connection portion 500, and by this, the lower semiconductor package 1000 may be electrically connected to the upper semiconductor package 2000.

According to the embodiment, the seed layer SDL may be removed according to irradiation of laser beams when the second wiring layers MLB that are fine circuit patterns of the redistribution substrate 200 are formed, and an etching process for removing the seed layer SDL around the first wiring layers MLA is performed while the second wiring layers MLB are covered and protected by the cover layer CL, so that the second wiring layers MLB that are fine circuit patterns may not be etched during the etching process. Further, the surfaces of the first wiring layers MLA may be partly etched during the etching process, thereby the surface roughness of the first wiring layers MLA may be relatively large and the surface roughness of the second wiring layers MLB may be relatively small.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A redistribution substrate comprising:
an insulating layer; and
a first wiring layer and a second wiring layer of which at least a portion is embedded in the insulating layer,
wherein the first wiring layer and the second wiring layer have different widths, and
the first wiring layer and the second wiring layer have different surface roughness.

2. The redistribution substrate of claim 1, wherein
the width of the first wiring layer is greater than the width of the second wiring layer, and
the surface roughness of the first wiring layer is greater than the surface roughness of the second wiring layer.

3. The redistribution substrate of claim 2, wherein
the surface of the first wiring layer includes a portion that is at least partly etched.

4. The redistribution substrate of claim 3, further comprising
a seed layer disposed below the first wiring layer and the second wiring layer.

5. The redistribution substrate of claim 2, wherein
the width of the second wiring layer is equal to or less than about 1 μm to about 3 μm, and a distance between an adjacent pair of the second wiring layers is equal to or less than about 2 μm to about 4 μm.

6. The redistribution substrate of claim 5, wherein
the width of the second wiring layer is equal to or less than about 2 μm, and a distance between the adjacent pair of the second wiring layers is equal to or less than about 3 μm.

7. A method for manufacturing a redistribution substrate comprising:
forming a seed layer on an insulating layer;
forming, within a first region of the insulating layer, a first wiring layer on the seed layer;
forming, within a second region of the insulating layer, a second wiring layer on the seed layer, the second wiring layer having a width that is different from a width of the first wiring layer;
removing the seed layer formed on the second region and not overlapping the second wiring layer by a first method; and
removing the seed layer formed on the first region and not overlapping the first wiring layer by a second method that is different from the first method.

8. The method of claim 7, wherein
the width of the first wiring layer is greater than the width of the second wiring layer, and
the first method includes irradiating laser beams onto the second region.

9. The method of claim 8, wherein
the laser beams have a linear beam form.

10. The method of claim 9, wherein
the laser beams are excimer laser beams.

11. The method of claim 9, wherein
the laser beams are ultraviolet laser beams.

12. The method of claim 8, wherein
in the irradiating of laser beams, gas is generated in the insulating layer, and the gas spurts onto the seed layer.

13. The method of claim 7, wherein
the width of the first wiring layer is greater than the width of the second wiring layer, and
the second method includes etching the seed layer formed on the first region.

14. The method of claim 13, wherein
the second method includes forming a cover layer to cover the second region, and
performing the etching with the cover layer as an etching mask.

15. The method of claim 13, wherein
the etching includes wet etching the seed layer formed on the first region.

16. The method of claim 13, wherein
at least a portion of a surface of the first wiring layer is etched during the etching.

17. A semiconductor package comprising:
a first redistribution substrate and a second redistribution substrate; and
a semiconductor chip disposed between the first redistribution substrate and the second redistribution substrate,
wherein the first redistribution substrate includes
an insulating layer, and
a first wiring layer and a second wiring layer at least partly embedded in the insulating layer,
the first wiring layer and the second wiring layer have different widths, and
the first wiring layer and the second wiring layer have different surface roughness.

18. The semiconductor package of claim 17, wherein
the width of the first wiring layer is greater than the width of the second wiring layer, and
the surface roughness of the first wiring layer is greater than the surface roughness of the second wiring layer.

19. The semiconductor package of claim 18, wherein
a surface of the first wiring layer includes a portion which is at least partly etched.

20. The semiconductor package of claim 19, further comprising
a seed layer disposed below the first wiring layer and the second wiring layer.
